(19) United States
(12) Patent Application Publication
(10) Pub. No.: US 2025/0318152 A1
(43) Pub. Date: Oct. 9, 2025

(54) SEMICONDUCTOR DEVICE WITH TOP SUPPORT LAYER AND METHOD FOR FABRICATING THE SAME

(71) Applicant: NANYA TECHNOLOGY CORPORATION, NEW TAIPEI CITY (TW)

(72) Inventor: CHUN-HENG WU, NEW TAIPEI CITY (TW)

(21) Appl. No.: 18/664,613

(22) Filed: May 15, 2024

Related U.S. Application Data
(62) Division of application No. 18/625,497, filed on Apr. 3, 2024.

(51) Int. Cl. H10D 1/00; H10D 1/68

(52) U.S. Cl. CPC H10D 1/042; H10D 1/716

(57) ABSTRACT

The present application discloses a semiconductor device and a method for fabricating the semiconductor device. The semiconductor device includes a substrate; a bottom electrode positioned over the substrate and including a container-shaped profile; and a top support layer overhung the substrate and attached to the bottom electrode. A thickness ratio of a thickness of the top support layer to a thickness of the bottom electrode is between about 3.0% and about 8.0%.

### CROSS-REFERENCE TO RELATED APPLICATION

This application is a divisional application of U.S. Non-Provisional application Ser. No. 18/625,497 filed Apr. 3, 2024, which is incorporated herein by reference in its entirety.

### TECHNICAL FIELD

The present disclosure relates to a semiconductor device and a method for fabricating the semiconductor device, and more particularly, to a semiconductor device with a top support layer and a method for fabricating the semiconductor device with the top support layer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a bottom electrode positioned over the substrate and including a container-shaped profile; and a top support layer overhung the substrate and attached to the bottom electrode. A thickness ratio of a thickness of the top support layer to a thickness of the bottom electrode is between about 3.0% and about 8.0%.

Another aspect of the present disclosure provides a semiconductor device including a substrate; a bottom electrode including a bottom portion positioned over the substrate and extending parallel to a top surface of the substrate, a first wall portion extending upward and from the bottom portion, and a second wall portion extending upward and from the bottom portion, and distant from the first wall portion; a first support layer positioned over the substrate and surrounding the first wall portion and the second wall portion; a second support layer positioned over the first support layer and surrounding the first wall portion and the second wall portion; and a third support layer positioned over the second support layer and surrounding the second wall portion. A thickness ratio of a thickness of the top support layer to a thickness of the bottom electrode is between about 3.0% and about 8.0%.

Another aspect of the present disclosure provides a method for fabricating a semiconductor device including forming a landing area over a substrate; sequentially forming a first support layer, a first material layer, a second support layer, a top material layer, a third support layer, and a bottom mask layer over the landing area; forming a first recess penetrating the bottom mask layer, the third support layer, the top material layer, the second support layer, the first material layer, and the first support layer and exposing the landing area; conformally forming a bottom electrode material layer on the bottom mask layer and the first recess, forming a sacrificial material to fill the first recess, and performing a planarization process to expose the bottom mask layer; performing a first etching process to selectively remove the bottom mask layer; performing a second etching process to selectively remove the bottom electrode material layer above the third support layer to turn the bottom electrode material layer into a bottom electrode; and performing a third etching process to remove the sacrificial material. An etching rate ratio of the bottom mask layer to the third support layer is greater than 1000 during the first etching process. An etching rate ratio of the bottom electrode material layer to the third support layer is greater than 100 during the second etching process.

Due to the design of the semiconductor device of the present disclosure, the consumption of the third support layer (or top support layer) may be significantly reduced due to the high etching selectivity of the first etching process and the second etching process. Hence, the remaining thickness of the third support layer may be increased. As a result, the performance of the semiconductor device may be improved. In addition, by doping different dopants for different material layers, the bottom of the first recesses may be broadened. As a result, the performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 5 illustrate, in schematic cross-sectional view diagrams, part of a flow for fabricating the semiconductor device in accordance with one embodiment of the present disclosure;

FIG. 6 is a top view diagram of an intermediate semiconductor device of FIG. 5;

FIGS. 7 to 13 illustrate, in schematic cross-sectional view diagrams, part of the flow for fabricating the semiconductor device in accordance with one embodiment of the present disclosure;

FIG. 14 is a top view diagram of an intermediate semiconductor device of FIG. 13;

FIGS. 15 to 19 illustrate, in schematic cross-sectional view diagrams, part of the flow for fabricating the semiconductor device in accordance with one embodiment of the present disclosure; and

FIGS. 20 to 33 illustrate, in schematic cross-sectional view diagrams, a flow for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

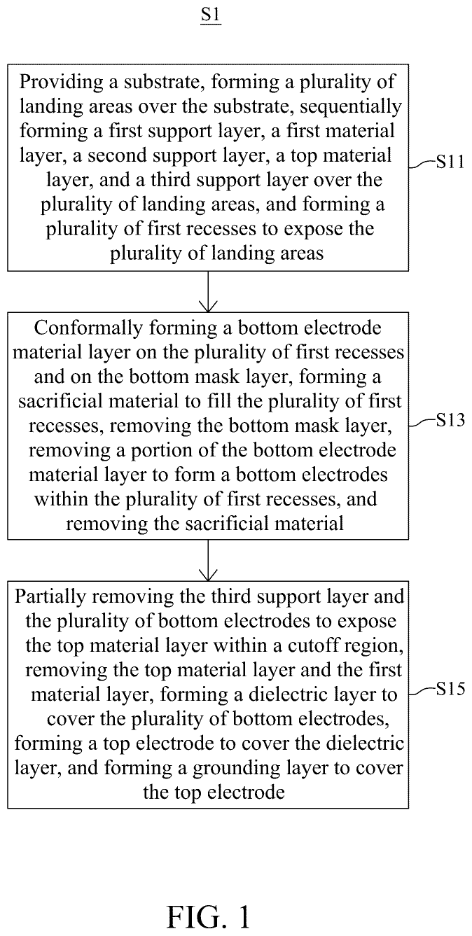

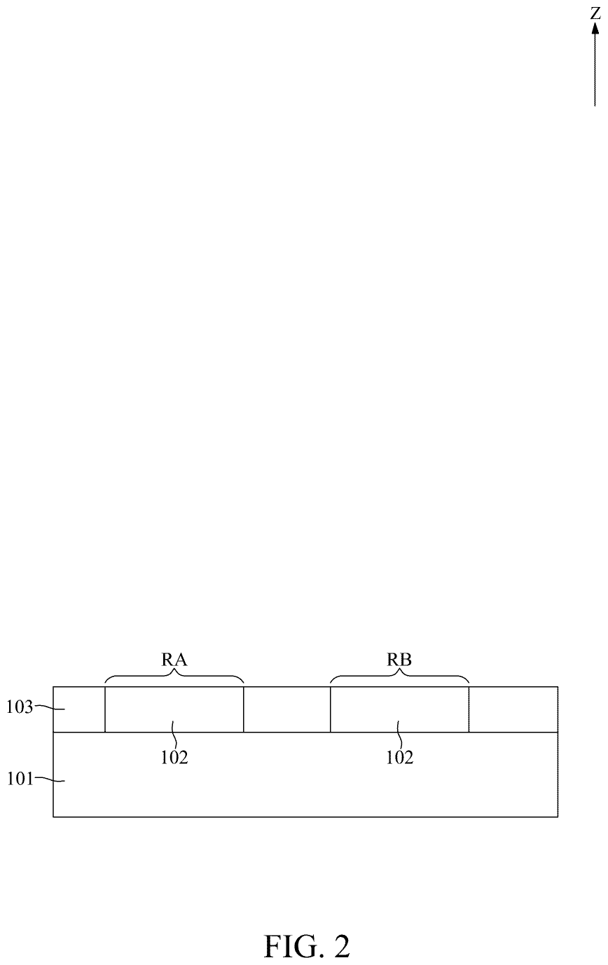

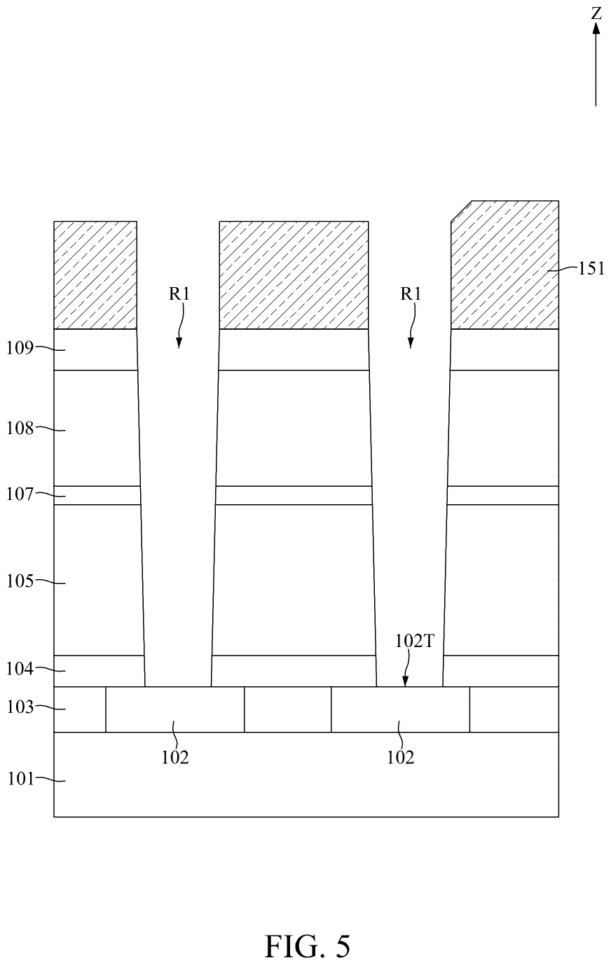

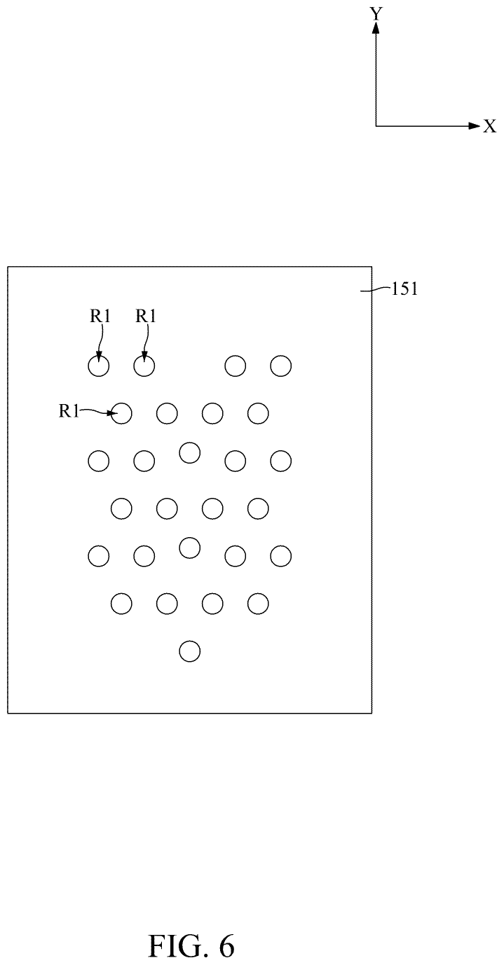

FIG. 1 illustrates, in a flowchart diagram form, a method 10 for fabricating a semiconductor device 1A in accordance with one embodiment of the present disclosure. FIGS. 2 to 5 illustrate, in schematic cross-sectional view diagrams, part of a flow for fabricating the semiconductor device 1A in accordance with one embodiment of the present disclosure. FIG. 6 is a top view diagram of an intermediate semiconductor device of FIG. 5.

With reference to FIGS. 1 to 6, at step S11, a substrate 101 may be provided, a plurality of landing areas 102 may be formed over the substrate 101, a first support layer 104 (also referred to as a bottom support layer), a first material layer 105, a second support layer 107 (also referred to as a middle support layer), a top material layer 108, and a third support layer 109 (also referred to as a top support layer) may be sequentially formed over the plurality of landing areas 102, and a plurality of first recesses R1 may be formed to expose the plurality of landing areas 102.

With reference to FIG. 2, a substrate 101 may be provided. An insulation layer 103 may be formed over the substrate 101, and the plurality of landing areas 102 may be formed in the insulation layer 103. For example, a landing area 102 may be formed over a first region RA of the substrate 101, and another landing area 102 may be formed over a second region RB that is different from the first region RA. In some embodiments, a planarization process such as chemical mechanical planarization (CMP) may be performed from above the insulation layer 103 and the landing areas 102.

The substrate 101 may be a semiconductor substrate, such as a bulk semiconductor, a semiconductor-on-insulator (SOI) substrate, or the like. The substrate 101 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of silicon, SiGe, GaAsP, AlInAs, AlGaAs, GaInAs, GaInP, and GaInAsP; any other suitable materials; or a combination thereof. In some embodiments, the alloy semiconductor substrate may be a silicon alloy with a gradient silicon feature in which Si and metal compositions change from one ratio at one location to another ratio at another location of the gradient silicon feature. For example, the alloy semiconductor substrate may be a SiGe alloy with a gradient SiGe feature in which Si and Ge compositions change from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

In some embodiments, the substrate 101 may have a multilayer structure, or the substrate 101 may include a multilayer compound semiconductor structure. In some embodiments, the substrate 101 may include semiconductor devices, electrical components, electrical elements, or a combination thereof. In some embodiments, the substrate 101 may include transistors or functional units of transistors.

In some embodiments, the landing areas 102 may include conductive material such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, doped polycrystalline silicon, polycrystalline silicon germanium, polycrystalline germanium, or a combination thereof.

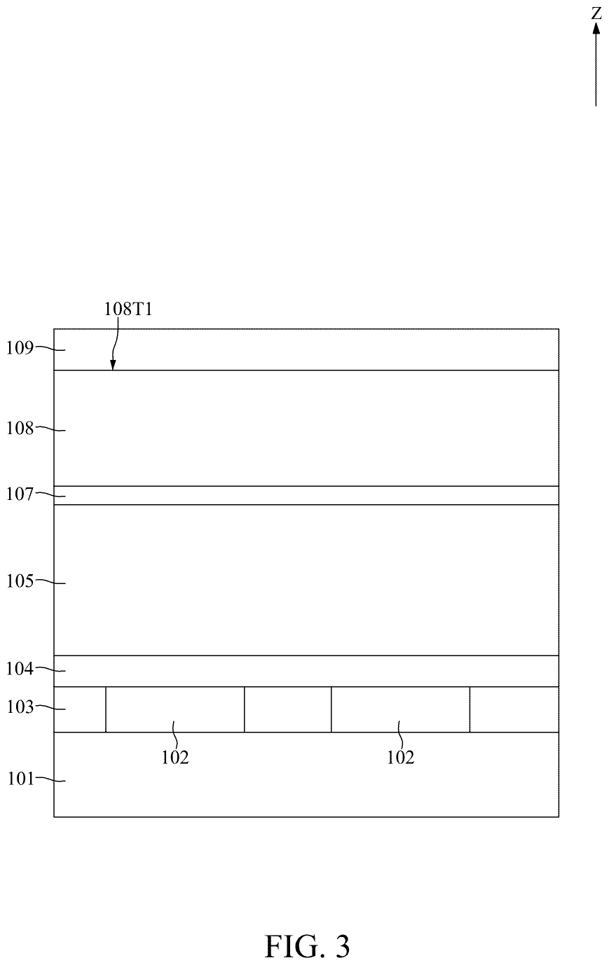

With reference to FIG. 3, the first support layer 104 may extend over the insulation layer 103 and the landing areas 102. In some embodiments, a material of the first support layer 104 may include silicon nitride (SiN). Alternatively, a material of the first support layer 104 can be another suitable material, such as an insulation material.

With reference to FIG. 3, the first material layer 105 may be formed over the first support layer 104. In some embodiments, wherein the first material layer 105 may be doped with a P-type dopant. For example, the first material layer 105 may be doped with boron, indium, gallium, or other suitable dopants. In some embodiments, the first material layer 105 may include polysilicon doped with a P-type dopant. In some embodiments, when the first material layer 105 is doped with boron, a concentration of boron dopant in the first material layer 105 may be in a range from 5E14 atoms/cm³ to about 5E15 atoms/cm³. In some embodiments, the first material layer 105 may include borophosphosilicate glass. In some embodiments, the dopant concentration in the first material layer 105 may be gradually decreased away from the first support layer 104 along the direction Z. The first material layer 105 may be in direct contact with the first support layer 104. In some embodiments, the first material layer 105 may have a thickness less than 800 nm.

With reference to FIG. 3, the second support layer 107 may be formed over the first material layer 105. A material of the second support layer 107 may be identical to the material of the first support layer 104. In some embodiments, a material of the second support layer 107 may include silicon nitride.

With reference to FIG. 3, the top material layer 108 (also referred to as the third material layer) may be formed over the second support layer 107. In some embodiments, the top material layer 108 may include, for example, silicon oxide. In some embodiments, the top material layer 108 may be formed by, for example, chemical vapor deposition using tetraethyl orthosilicate (TEOS) or other applicable deposition processes. In some embodiments, the thickness of the top material layer 108 may be less than the thickness of the first material layer 105. The top material layer 108 may be in direct contact with the second support layer 107. The top material layer 108 has a top surface 108T1.

With reference to FIG. 3, the third support layer 109 may be formed over the top surface 108T1 of the top material layer 108. A material of the third support layer 109 may be identical to the material of the first support layer 104 or the material of the second support layer 107. In some embodiments, a material of the third support layer 109 includes silicon nitride. In some embodiments, a total thickness of a stack of the first support layer 104, the first material layer 105, the second support layer 107, the top material layer 108, and the third support layer 109 may be in a range from 0.8 μm to about 1.2 μm.

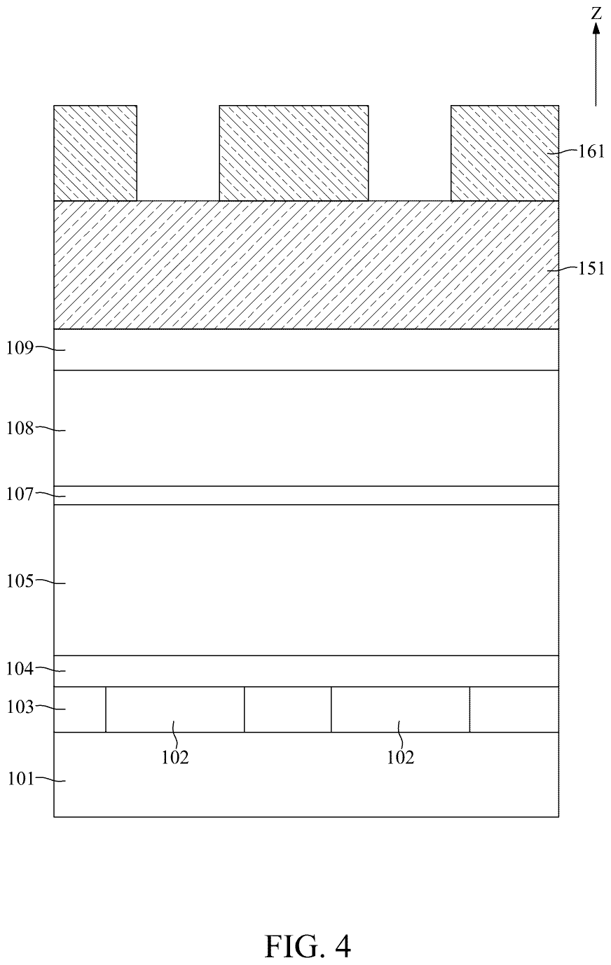

With reference to FIG. 4, a bottom mask layer 151 may be formed on the third support layer 109. In some embodiments, the bottom mask layer 151 may serve as a hard mask for forming the first recesses R1. In some embodiments, the bottom mask layer 151 may include polycrystalline silicon or other suitable materials having etching selectivity to silicon oxide and silicon nitride. In some embodiments, the bottom mask layer 151 may be formed by, for example, chemical vapor deposition or other suitable deposition processes. A first mask layer 161 may be formed on the bottom mask layer 151. In some embodiments, the first mask layer 161 may be a photoresist layer and may include the pattern of the first recesses R1.

With reference to FIG. 5, the plurality of first recesses R1 may be formed over the substrate 101 by performing a dry etching process using the first mask layer 161 as the mask. In some embodiments, the dry etching process may include applying plasma, such as fluorine-based plasma or fluorine-containing plasma. In some embodiments, each of the first recesses R1 may penetrate the first support layer 104, the first material layer 105, the second support layer 107, the top material layer 108, and the third support layer 109. The landing areas 102 may be exposed through the first recesses R1. In some embodiments, a cleaning process may be performed to remove residues generated in the dry etching process. In some embodiments, as depicted in FIG. 6, the first recesses R1 may be arranged in a staggered array. A position of each of the first recesses R1 corresponds to a position of one of the landing areas 102. In some embodiments, the first recesses R1 may include a tapered profile towards the substrate 101. In other words, the width of the first recess R1 may be gradually decreased towards the substrate 101. In some embodiments, an aspect ratio of first recess R1 may be greater than 35. In some embodiments, the top surface 102T of the landing area 102 may be partially exposed through the first recess R1. That is, a portion of the landing area 102 may be covered by the first support layer 104.

It should be noted that the uneven topography of the bottom mask layer 151 may be caused by the loading effect of the dry etching process.

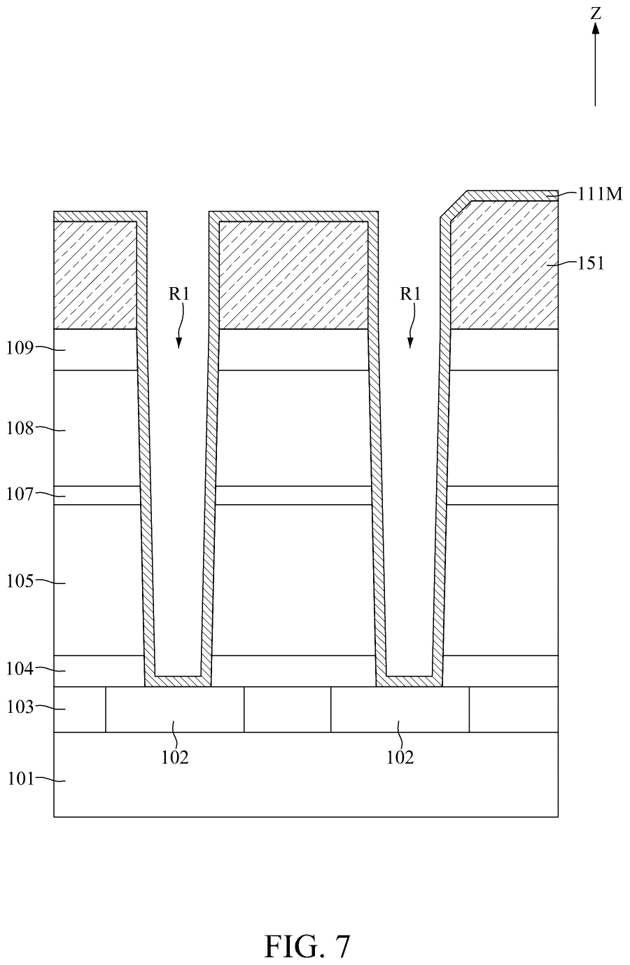

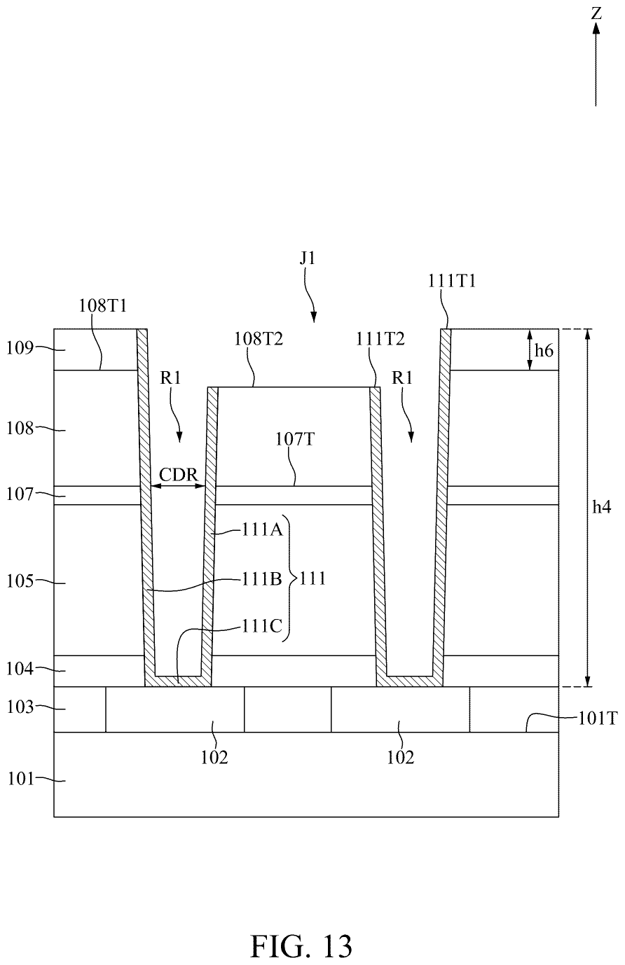

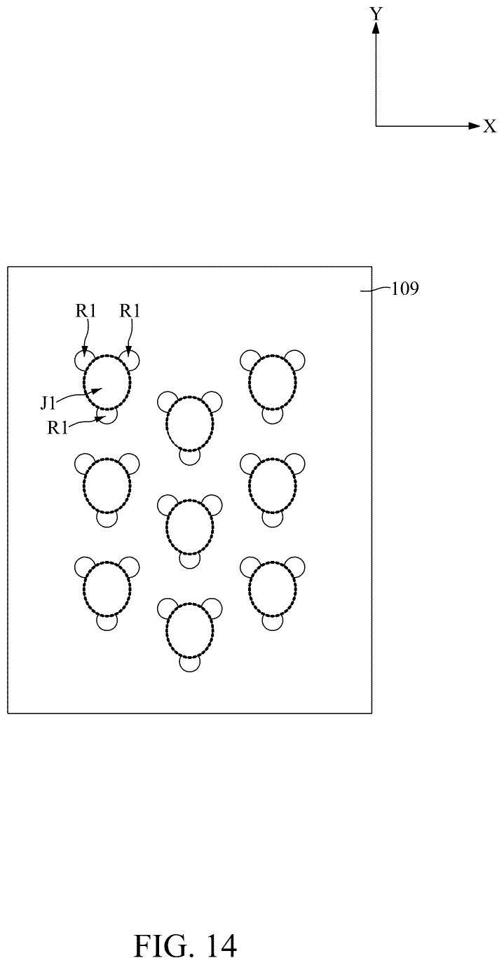

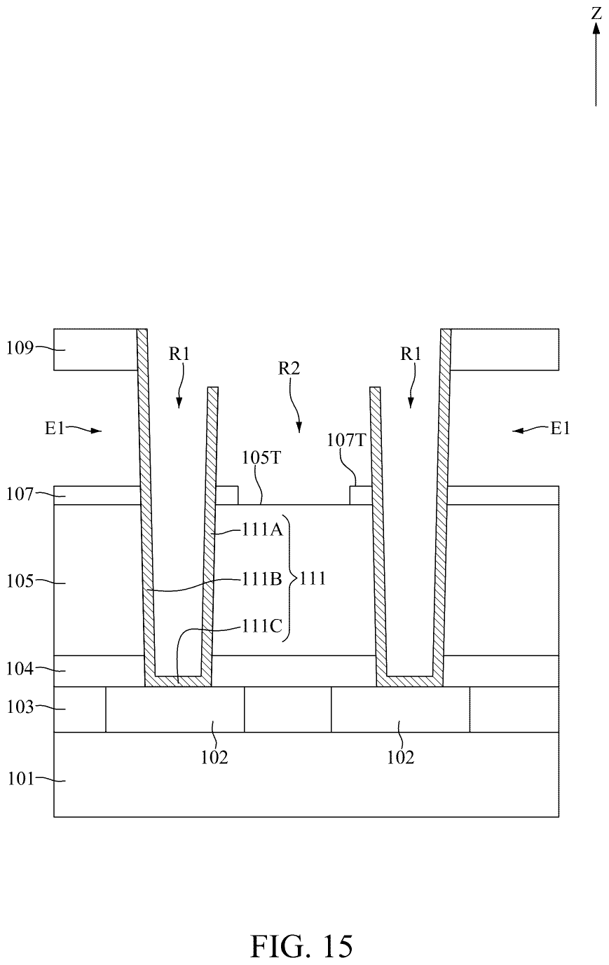

FIGS. 7 to 13 illustrate, in schematic cross-sectional view diagrams, part of the flow for fabricating the semiconductor device 1A in accordance with one embodiment of the present disclosure. FIG. 14 is a top view diagram of an intermediate semiconductor device of FIG. 13. FIGS. 15 to 19 illustrate, in schematic cross-sectional view diagrams, part of the flow for fabricating the semiconductor device 1A in accordance with one embodiment of the present disclosure.

With reference to FIG. 1 and FIGS. 7 to 12, at step S13, a bottom electrode material layer 111M may be conformally formed on the plurality of first recesses R1 and on the bottom mask layer 151, a sacrificial material 137 may be formed to fill the plurality of first recesses R1, the bottom mask layer 151 may be removed, a portion of the bottom electrode material layer 111M may be removed to form a plurality of bottom electrodes 111 within the plurality of first recesses R1, and the sacrificial material 137 may be removed.

With reference to FIG. 7, the bottom electrode material layer 111M may be formed in the first recesses R1, thus causing the bottom electrode material layer 111M to have a container-shaped profile. In the present disclosure, the term “container-shaped” or “shaped as a container” may be referred to an object having a bottom and a sidewall portion extended from the bottom, and a portion of a space above the bottom is at least partially surrounded by the sidewall portion in lateral direction. The bottom electrode material layer 111M may conform to a profile of the first recess R1. In some embodiments, the bottom electrode material layer 111M may further cover the top surface 151T of the bottom mask layer 151 and the top surface 102T of the landing area 102. In some embodiments, the bottom electrode material layer 111M may include titanium nitride (TiN), titanium silicon nitride (TiSiN), or a combination thereof. In some embodiments, the bottom electrode material layer 111M may be formed by blanket deposition, chemical vapor deposition (CVD), physical vapor deposition (PVD), atomic layer deposition (ALD), or other applicable deposition process.

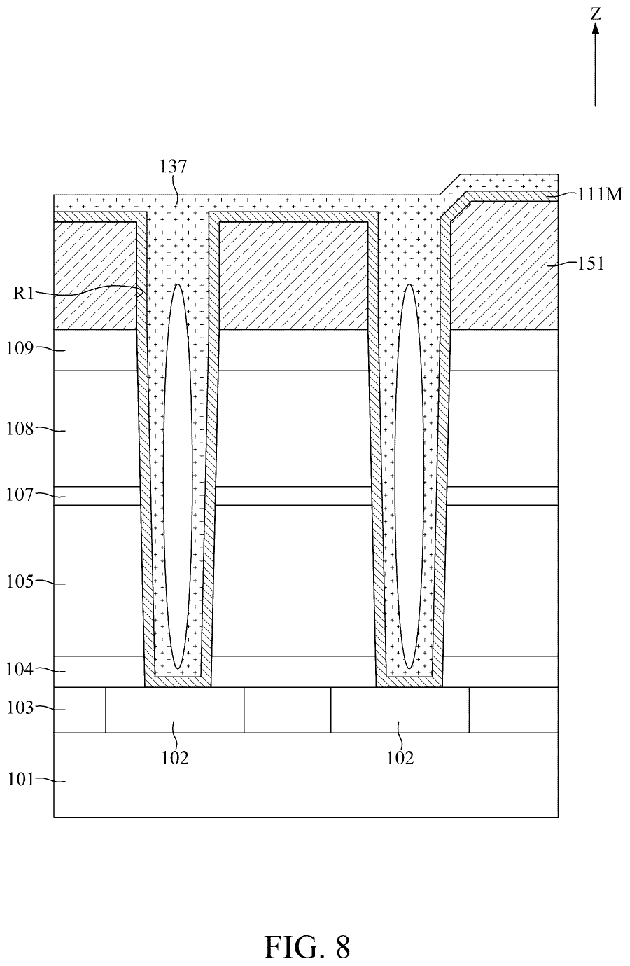

With reference to FIG. 8, the sacrificial material 137 may be formed over the substrate 101 and fill the first recesses R1. In some embodiments, the bottom electrode material layer 111M may be completely covered by the sacrificial material 137. In some embodiments, the sacrificial material 137 may include material having etching selectivity to the bottom electrode material layer 111M. In some embodiments, the sacrificial material 137 may include material having etching selectivity to the bottom electrode material layer 111M and the bottom mask layer 151. In some embodiments, the sacrificial material 137 may include an oxide, such as silicon oxide. In some embodiments, the sacrificial material 137 may include a photoresist. In some embodiments, the sacrificial material 137 may be formed by a deposition process, such as a CVD process, a PVD process, an ALD process, or a spin-off process.

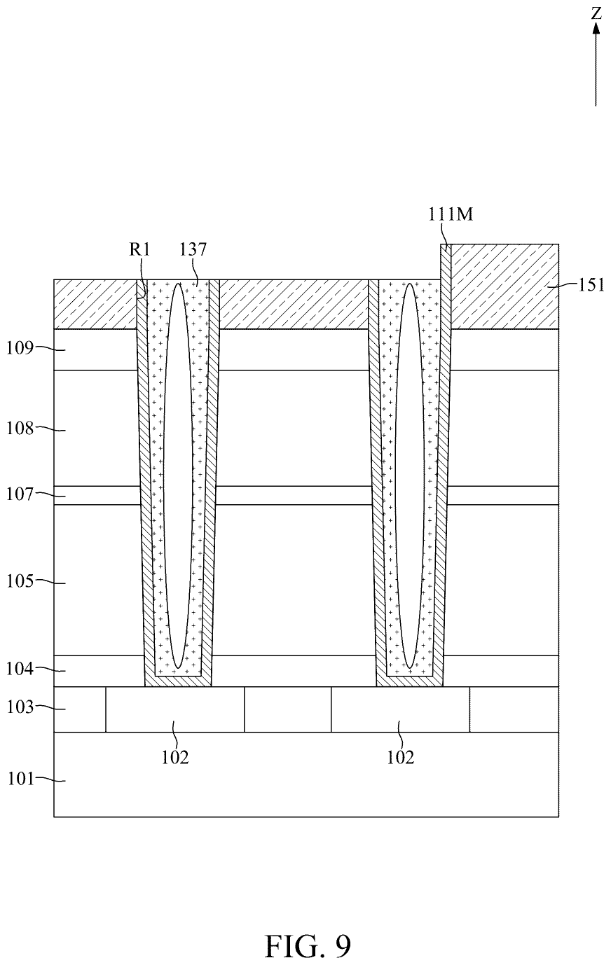

With reference to FIG. 9, a planarization process, such as chemical mechanical polishing, may be performed until the bottom mask layer 151 is exposed to remove excess material and provide a substantially flat surface for subsequent processing steps. Portions of the bottom electrode material layer 111M, the bottom mask layer 151, and the sacrificial material 137 may be removed during the planarization process. The sacrificial material 137 may be separated into multiple portions within the first recesses R1, respectively and correspondingly. The bottom electrode material layer 111M may be separated into multiple portions over each landing area 102 after the planarization process. For example, one portion of the bottom electrode material layer 111M may be formed over the first region RA, and another portion of the bottom electrode material layer 111M may be formed over the second region RB. Each portion of the bottom electrode material layer 111M may have a container-shaped profile.

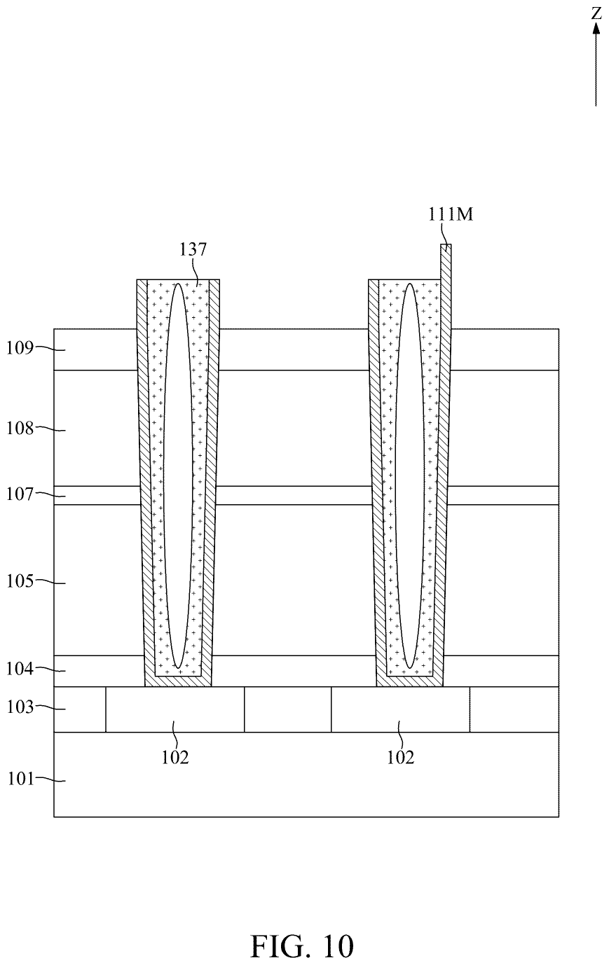

With reference to FIG. 10, a first etching process may be performed to selectively remove the bottom mask layer 151. In some embodiments, the first etching process may be a gas etching process. In some embodiments, the first etching process may use radicals (e.g., hydrogen radicals or fluorine radicals) to remove the bottom mask layer 151. In some embodiments, ions of the first etching process may be filtered. In some embodiments, the reaction gas of the first etching process may include, for example, ammonia, hydrogen fluoride, fluorine, nitrogen trifluoride, and/or hydrogen. In some embodiments, the first etching process may include carrier gas such as nitrogen and/or argon. In some embodiments, the process temperature of the first etching process may be between about 20° C. and about 120° C.

In some embodiments, during the first etching process, the etching rate ratio of the bottom mask layer 151 to the third support layer 109 may be greater than 1000. In some embodiments, during the first etching process, the etching rate ratio of doped polycrystalline silicon to silicon nitride may be greater than 1000. It should be noted that the consumption of the third support layer 109 may be significantly reduced due to the high etching selectivity of the first etching process.

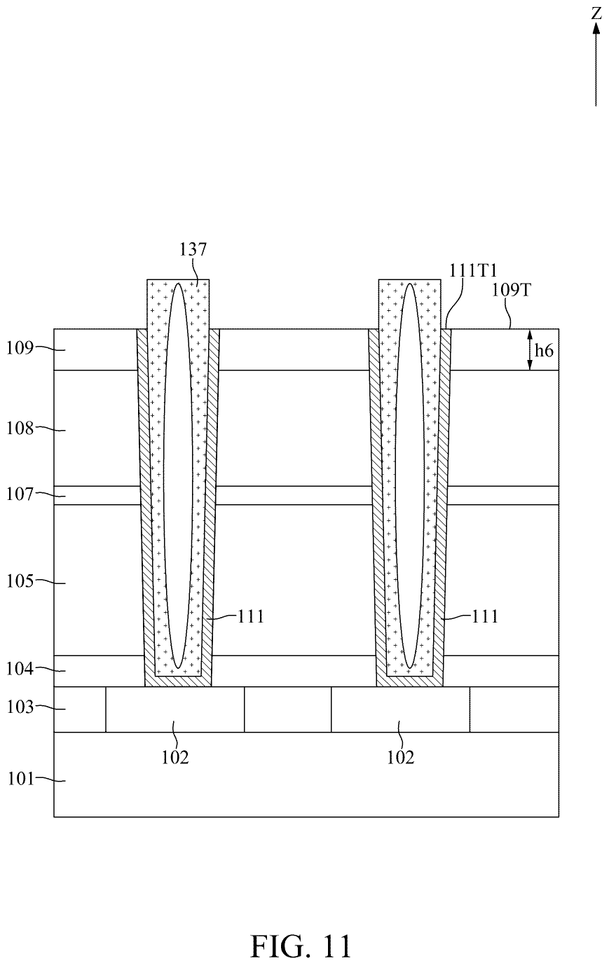

With reference to FIG. 11, a second etching process may be performed to remove the bottom electrode material layer 111M above the third support layer 109. After the second etching process, the remaining bottom electrode material layer 111M may be referred to as the plurality of bottom electrodes 111. The bottom electrode 111 may have a container-shaped profile. In some embodiments, the top surface 111T1 of the bottom electrode 111 and the top surface 109T of the third support layer 109 may be substantially coplanar.

In some embodiments, the second etching process may be a gas etching process. In some embodiments, the second etching process may use radicals (e.g., hydrogen radicals or fluorine radicals) to remove the exposed bottom electrode material layer 111M. In some embodiments, ions of the second etching process may be filtered. In some embodiments, the reaction gas of the second etching process may include, for example, ammonia, hydrogen fluoride, fluorine, nitrogen trifluoride, and/or hydrogen. In some embodiments, the second etching process may include carrier gas such as nitrogen and/or argon. In some embodiments, the process temperature of the second etching process may be between about 250° C. and about 350° C.

In some embodiments, during the second etching process, the etching rate ratio of the bottom electrode material layer 111M to the third support layer 109 may be greater than 100. In some embodiments, during the second etching process, the etching rate ratio of tungsten to silicon nitride may be greater than 100. It should be noted that the consumption of the third support layer 109 may be significantly reduced due to the high etching selectivity of the second etching process.

In some embodiments, the thickness loss of the third support layer 109 after the first and second etching process may be less than about 50%, about 45%, about 40%, about 35%, or about 30%. The thickness loss of the third support layer 109 can be calculated by the thickness of the third support layer 109 before the first etching process divided by the thickness of the third support layer 109 after the second etching process. In some embodiments, the thickness loss of the third support layer 109 after the first and second etching process may be less than about 40 nm, about 35 nm, about 30 nm, or about 25 nm. In some embodiments, the thickness h6 of the third support layer 109 after the first and second etching process may be greater than about 40 nm, about 45 nm, about 50 nm, about 55 nm, or about 60 nm.

In some embodiments, the first etching process and the second etching process may be performed in the same process chamber.

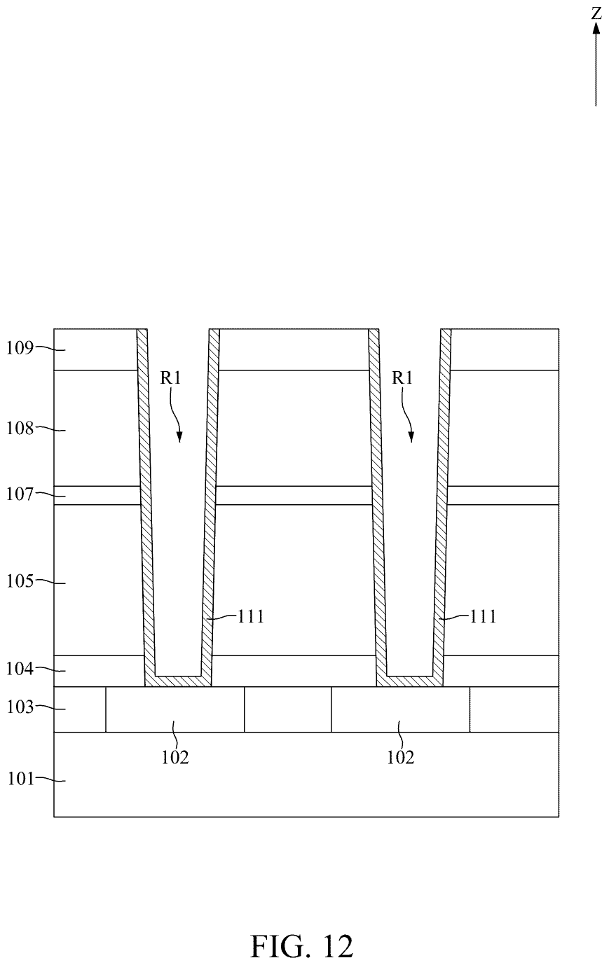

With reference to FIG. 12, a third etching process may be performed to completely remove the sacrificial material 137. In some embodiments, during the third etching process, the etching selectivity of the sacrificial material 137 with respect to the bottom electrode 111 may be relatively high. Therefore, the sacrificial material 137 may be removed by the etching process while the bottom electrode 111 may be substantially left. In some embodiments, the third etching process may be a wet etching process. In some embodiments, the third etching process may include diluted hydrofluoric acid.

With reference to FIG. 1 and FIGS. 13 to 19, at step S15, the third support layer 109 and the plurality of bottom electrodes 111 may be partially removed to expose the top material layer 108 within a cutoff region J1, the top material layer 108 and the first material layer 105 may be removed, a dielectric layer 112 may be formed to cover the plurality of bottom electrodes 111, a top electrode 113 may be formed to cover the dielectric layer 112, and a grounding layer 114 may be formed to cover the top electrode 113.

With reference to FIG. 13, the cutoff region J1 may be defined by a lithography process, wherein the cutoff region J1 connects to at least two first recesses R1. In some embodiments, each cutoff region J1 connects to three first recesses R1, as depicted in FIG. 14. Further, an etching process may be performed to remove a portion of the top material layer 108, a portion of the third support layer 109, and portions of the bottom electrodes 111 over the cutoff region J1. In some embodiments, the etching process may stop at a position in the top material layer 108, or, alternatively stated, the etching process may stop at a position above a top surface 107T of the second support layer 107. After such an etching process, a remaining portion of the top material layer 108 in the cutoff region J1 has a top surface 108T2 lower than the top surface 108T1 of the top material layer 108 that is outside of the cutoff region J1. In some embodiments, a cleaning process may be performed to remove residues generated during the etching process.

In some embodiments, after the etching process, the bottom electrode 111 may include a first wall portion 111A extending upward and adjacent to the cutoff region J1, a second wall portion 111B extending upward and positioned on a side away from the first wall portion 111A, and a bottom portion 111C over the landing area 102 and extending parallel to the top surface 101T of the substrate 101. In some embodiments, the dimension CDR between the first wall portion 111A and the second wall portion 111B may be tapered towards the bottom portion 111C.

The first wall portion 111A may have a top surface 111T2 lower than the top surface 108T1 of the top material layer 108. The top surface 111T2 may be lower than the top surface 111T1 of the second wall portion 111B. In some embodiments, the top surface 111T2 of the first wall portion 111A and the top surface 108T2 of the top material layer 108 at the cutoff region J1 may be substantially coplanar.

In some embodiments, the thickness ratio of the thickness h6 of the third support layer 109 to the thickness h4 of the bottom electrode 111 may be between about 3.0% and about 8.0% or between about 3.3% and about 7.5%. In some embodiments, the thickness h4 of bottom electrode 111 may be in a range from 0.8 μm to about 1.2 μm.

With reference to FIG. 15, the top material layer 108 may be removed by a removal process. In some embodiments, the removal process may include applying NF₃ and H₂, along with an application of plasma, over the third material layer 108. The removal process may have an etching rate on Si significantly greater than an etching rate on SiN; for example, around 2000:1. Further, when the targeted layer to be etched may be partially covered by SiN, the previously mentioned etching recipe is an effective process. After the removal process is performed, the third support layer 109 may remain adhered to the bottom electrode 111 and overhang the second support layer 107. In some embodiments, the third support layer 109 may be attached to the second wall portion 111B of the bottom electrode 111.

The top surface 107T of the second support layer 107 may be exposed, and an empty space E1 may be formed between the second support layer 107 and the third support layer 109.

After the removal process, a punch-through process may be performed to remove a portion of the second support layer 107 in the cutoff region J1 (as shown in FIG. 13). Therefore, a second recess R2 may be formed in the second support layer 107, and a top surface 105T of the first material layer 105 may be exposed through the second recess R2. The second recess R2 may be positioned between the first wall portions 111A of the bottom electrodes 111.

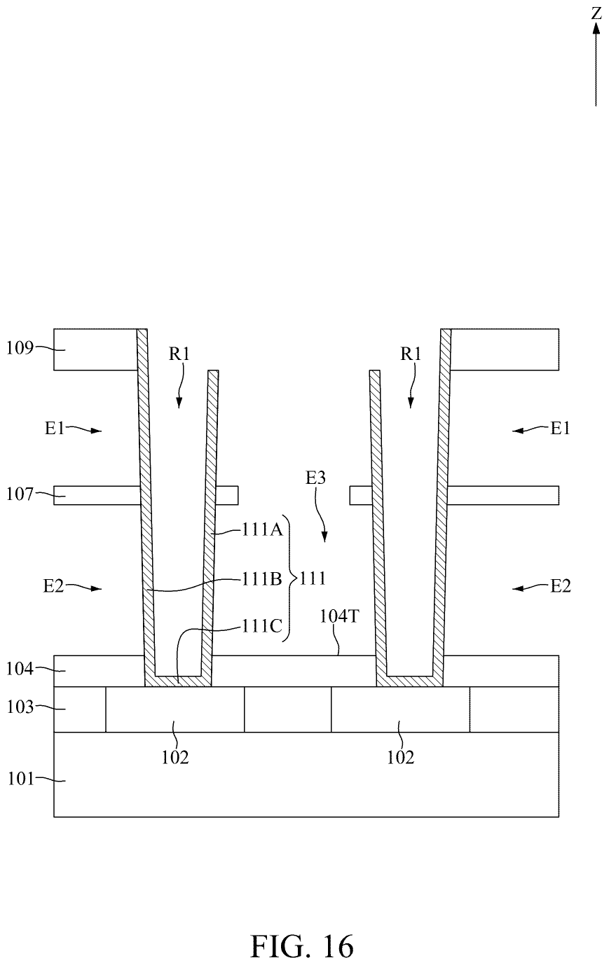

With reference to FIG. 16, the first material layer 105 may be removed by a removal process. In some embodiments, the removal process may include applying NF₃ and H₂, along with an application of plasma, over the first material layer 105. Such a removal process may have an etching rate on Si significantly greater than an etching rate on SiN, for example, around 2000:1. After performing the removal process, the second support layer 107 may remain adhered to the bottom electrode 111 and overhang the first support layer 104. In some embodiments, the etching chemical enters through the second recess R2 depicted in FIG. 15. In some embodiments, the second support layer 107 may be attached to the second wall portion 111B and the first wall portion 111A of the bottom electrode 111. The top surface 104T of the first support layer 104 may be exposed. An empty space E2 may be formed between the first support layer 104 and the second support layer 107. An empty space E3 may be formed between the first wall portions 111A of the bottom electrodes 111.

In summary, the first material layer 105 and the top material layer 108 are removed. The first support layer 104, the second support layer 107, the third support layer 109, and the bottom electrodes 111 remain in place.

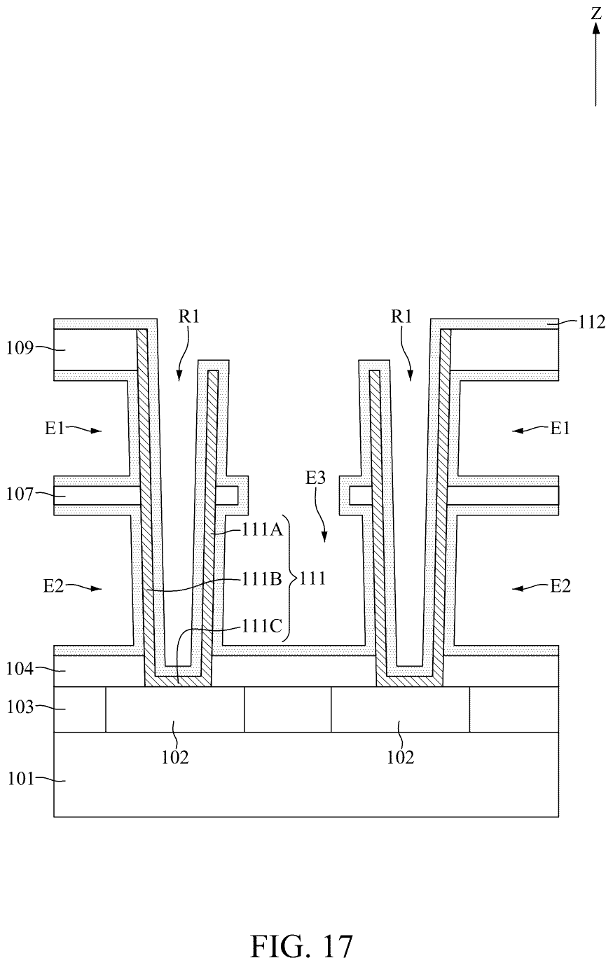

With reference to FIG. 17, the dielectric layer 112 may be conformally formed to cover the surface of the third support layer 109, the second support layer 107, the first support layer 104, and the bottom electrodes 111. In some embodiments, the dielectric layer 112 may include a single layer or multiple layers. In some embodiments, the dielectric layer 112 may include SiO₂, a dielectric material with high dielectric constant (high-k), such as ZrO₂, HfO₂, TiO₂, AlO, or a combination thereof. For example, the dielectric layer 112 may be a tri-layer structure including two layers of aluminum oxide and a layer of zirconium oxide disposed between them. Moreover, in some embodiments, the dielectric layer 112 may be formed by a conformal deposition process, such as a CVD process, a PVD process, or an ALD process.

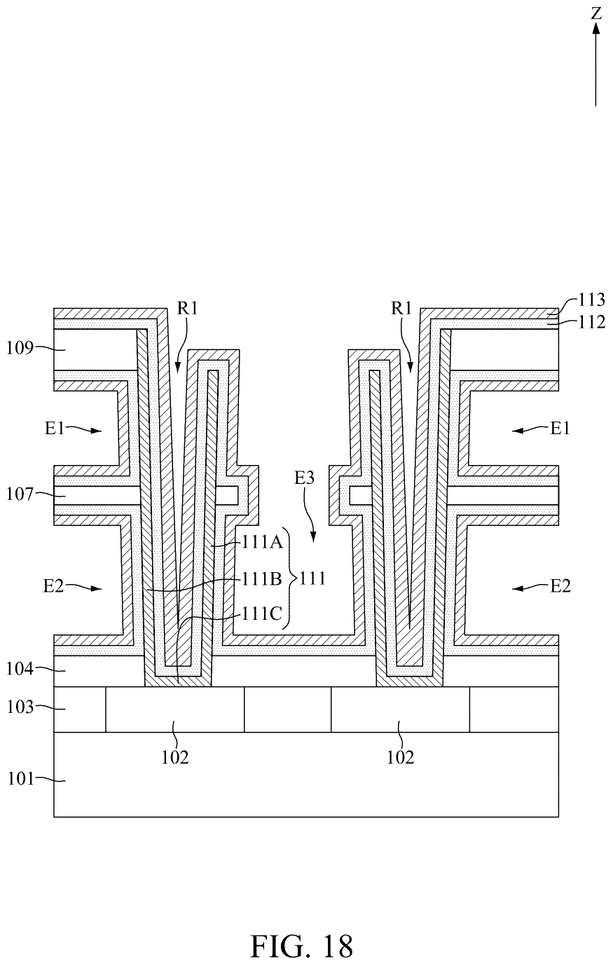

With reference to FIG. 18, the top electrode 113 may be conformally formed to cover the dielectric layer 112. In some embodiments, the top electrode 113 may include titanium nitride (TiIN), titanium silicon nitride (TiSiN), or a combination thereof. In some embodiments, the top conductive layer 113 is formed by a conformal deposition process, such as a CVD process, a PVD process, or an ALD process.

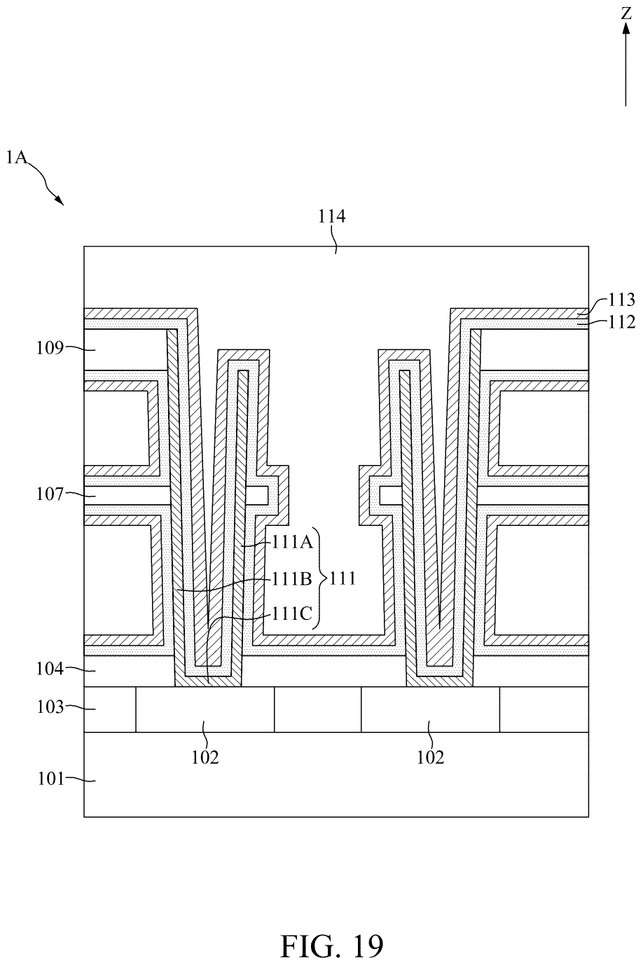

With reference to FIG. 19, the grounding layer 114 may be formed on the top electrode 113 and fill the empty space E1, the empty space E2, the empty space E3, and the first recesses R1. In some embodiments, the grounding layer 114 doped polycrystalline silicon, polycrystalline silicon germanium, polycrystalline germanium, or a combination thereof. In some embodiments, the grounding layer 114 may be doped with P-type dopant or N-type dopant. P-type dopant may include boron, indium, or gallium. N-type dopant may include phosphorus, arsenic, antimony, or bismuth. In some embodiments, the grounding layer 114 may be formed by, for example, a CVD process or other applicable deposition processes.

In some embodiments, an anneal process may be performed to activate the grounding layer 114. The temperature of the anneal process may be between about 800° C. and about 1250° C. The anneal process may have a process duration between about 1 millisecond and about 500 milliseconds. The anneal process may be, for example, a rapid thermal anneal, a laser spike anneal, or a flash lamp anneal.

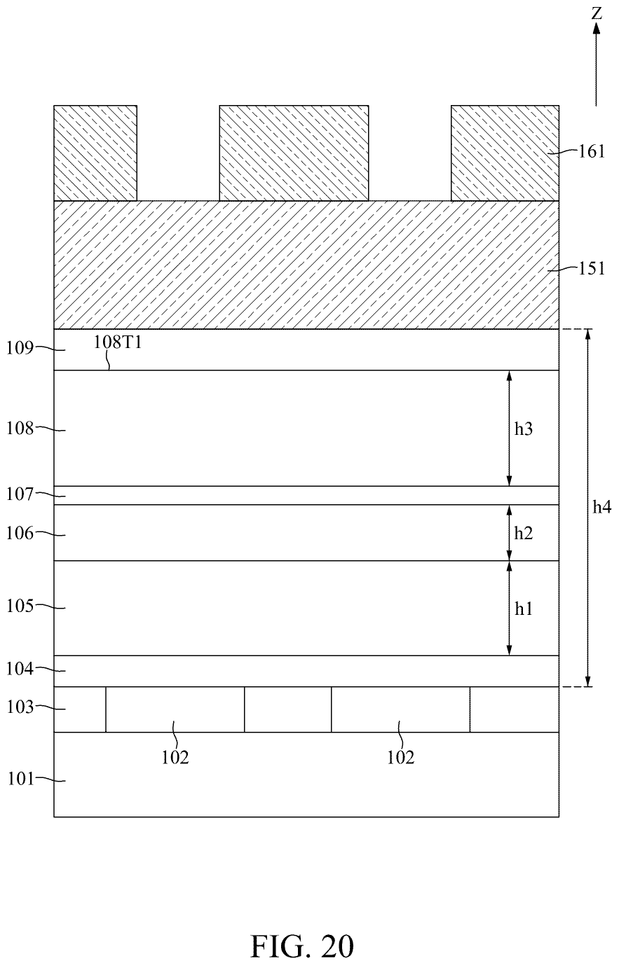

FIGS. 20 to 33 illustrate, in schematic cross-sectional view diagrams, a flow for fabricating a semiconductor device 1B in accordance with another embodiment of the present disclosure.

With reference to FIG. 20, the substrate 101, the plurality of landing areas 102, the insulation layer 103, the first support layer 104 may be formed with a procedure similar to that illustrated in FIGS. 2 and 3, and descriptions thereof are not repeated herein.

The first material layer 105 may be formed over the first support layer 104, wherein the first material layer 105 may be doped with an N-type dopant. For example, the first material layer 105 can be doped with phosphorus, arsenic, antimony, bismuth, or other suitable dopants. In some embodiments, the first material layer 105 may include polysilicon doped with an N-type dopant. The first material layer 105 may have a first thickness h1. In some embodiments, the first thickness h1 of the first material layer 105 may be less than 400 nm. In some embodiments, when the first material layer 105 is doped with phosphorus, a concentration of phosphorus dopant in the first material layer 105 may be in a range from 5E14 atoms/cm³ to about 5E15 atoms/cm³.

A second material layer 106 may be formed over the first material layer 105. The second material layer 106 may have a second thickness h2. In some embodiments, the second thickness h2 of the second material layer 106 may be less than the first thickness h1 of the first material layer 105. In some embodiments, the second thickness h2 of the second material layer 106 may be less than 200 nm. In some embodiments, the second material layer 106 may include undoped polysilicon (which can be referred to as intrinsic polysilicon), that is, without significant dopant therein. The second material layer 106 may be in direct contact with the first material layer 105.

The second support layer 107 may be formed on the second material layer 106. A material of the second support layer 107 may be identical to the material of the first support layer 104. In some embodiments, a material of the second support layer 107 may include silicon nitride.

The top material layer 108 may be formed over the second support layer 107, wherein the top material layer 108 may be doped with a P-type dopant. For example, the top material layer 108 can be doped with boron, indium, gallium, or other suitable dopants. The top material layer 108 may have a third thickness h3. In some embodiments, the third thickness h3 of the top material layer 108 may be greater than the first thickness h1 of the first material layer 105. In some embodiments, the third thickness h3 of the top material layer 108 may be greater than the second thickness h2 of the second material layer 106. In some embodiments, the third thickness h3 of the top material layer 108 may be less than 500 nm. In some embodiments, a sum of the first thickness h1 of the first material layer 105 and the second thickness h2 of the second material layer 106 is greater than the third thickness h3 of the top material layer 108.

In some embodiments, the top material layer 108 may include polysilicon doped with a P-type dopant. In some embodiments, when the top material layer 108 is doped with boron, a concentration of boron dopant in the top material layer 108 is in a range from 5E14 atoms/cm³ to about 5E15 atoms/cm³. The top material layer 108 may be in direct contact with the second support layer 107. The top material layer 108 has a top surface 108T1.

The third support layer 109, the bottom mask layer 151, and the first mask layer 161 may be formed with a procedure similar to that illustrated in FIGS. 3 and 4, and descriptions thereof are not repeated herein.

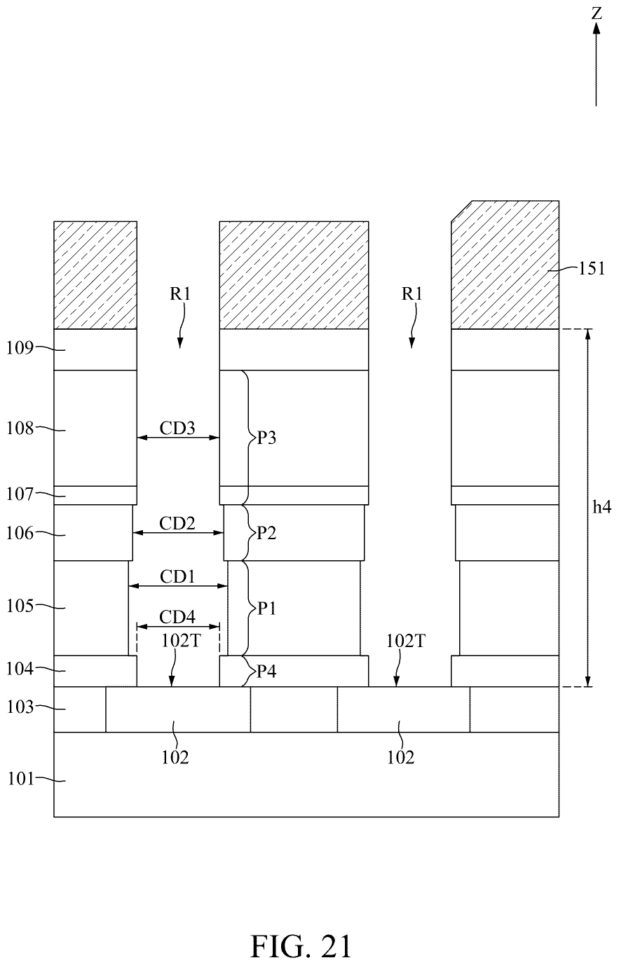

With reference to FIG. 21, a plurality of first recesses R1 may be formed over the substrate 101 by performing a dry etching process. In some embodiments, the dry etching process may include applying plasma, such as fluorine-based plasma or fluorine-containing plasma. In some embodiments, each of the first recesses R1 may penetrate the first support layer 104, the first material layer 105, the second material layer 106, the second support layer 107, the top material layer 108, and the third support layer 109. The landing areas 102 may be exposed through the first recesses R1. In some embodiments, positions of the first recesses R1 may be defined by one or more lithography operation(s), and a cleaning process can be performed to remove residues generated in the dry etching process. In some embodiments, the first recesses R1 may be arranged in a staggered array in a top-view perspective (as shown in FIG. 6). A position of each of the first recesses R1 may correspond to a position of one of the landing areas 102.

In some embodiments, an aspect ratio of the first recess R1 may be greater than 35. The first recess R1 may have a first portion P1 laterally surrounded by the first material layer 105, a second portion P2 laterally surrounded by the second material layer 106, a third portion P3 laterally surrounded by the third material layer 108, and a fourth portion P4 laterally surrounded by the first support layer 104. The third portion P3 may be above the second portion P2, the second portion P2 may be above the first portion P1, and the first portion P1 may be above the fourth portion P4.

An etching rate of the dry etching process on the first material layer 105 may be greater than an etching rate of the dry etching process on the second material layer 106. Further, the etching rate of the dry etching process on the second material layer 106 may be greater than the etching rate of the dry etching process on the third material layer 108. Detailedly, by doping the first material layer 105 with an N-type dopant in a predetermined concentration, the etching rate of the dry etching process on the first material layer 105 in a lateral direction can be enhanced. In contrast, by doping the third material layer 108 with a P-type dopant in a predetermined concentration, the etching rate of the dry etching process on the third material layer 108 in a lateral direction can be reduced.

In a comparative embodiment, a recess (not shown) with high aspect ratio and narrower dimension at bottom (with respect to the dimension at top) may lead to a lower capacitance of a capacitor further formed in the recess. In contrast, doping the first material layer 105 and the third material layer 108 with different types of dopants and disposing the second material layer 106 without significant doping between the first material layer 105 and the third material layer 108, can widen the bottom of the first recess R1. This improvement in the profile of the first recesses R1 may enhance the performance of the semiconductor device 1A.

Detailedly, a dimension CD1 of the first portion P1 may be greater than a dimension CD2 of the second portion P2. In some embodiments, the dimension CD2 of the second portion P2 may be greater than a dimension CD3 of the third portion P3. In some embodiments, the dimension CD1 of the first portion P1 may be greater than a dimension CD4 of the fourth portion P4. In some embodiments, the dimension CD1 may be greater than either the dimension CD2 or the dimension CD3. The aforementioned ranges of dopant concentrations in the material layers are designed to obtain desired values for the dimensions CD1, CD2 and CD3, with a difference between CD1 and CD3 within a predetermined range.

In some alternative embodiments, the dimension CD1 may be comparable to the dimension CD2, and the dimension CD2 may be comparable to the dimension CD3.

In some embodiments, a top surface 102T of the landing area 102 may be exposed through the fourth portion P4 of the first recess R1. A portion of the landing area 102 may be covered by the first support layer 104.

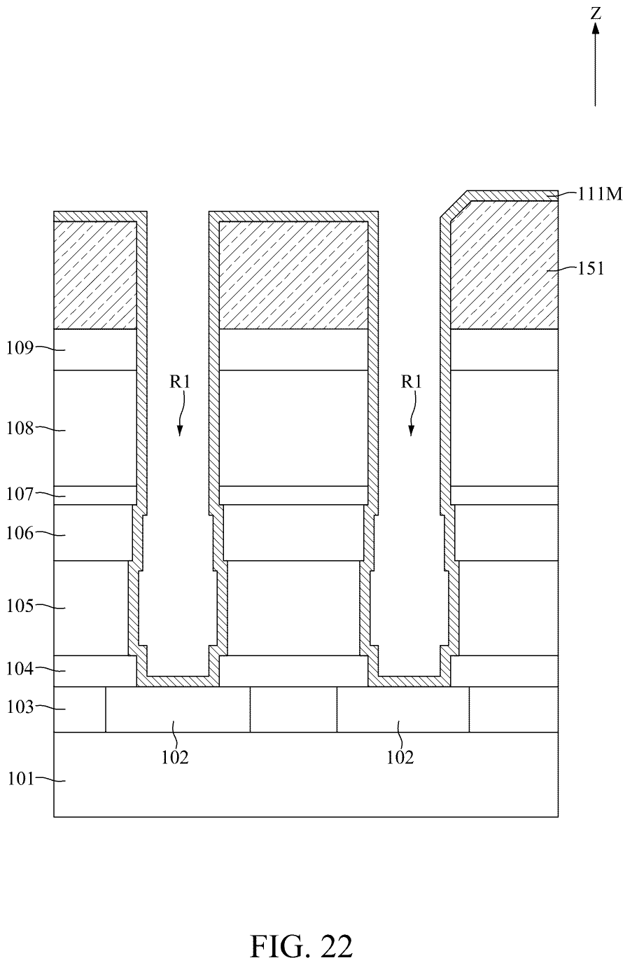

With reference to FIG. 22, the bottom electrode material layer 111M may be formed with a procedure similar to that illustrated in FIG. 7, and descriptions thereof are not repeated herein.

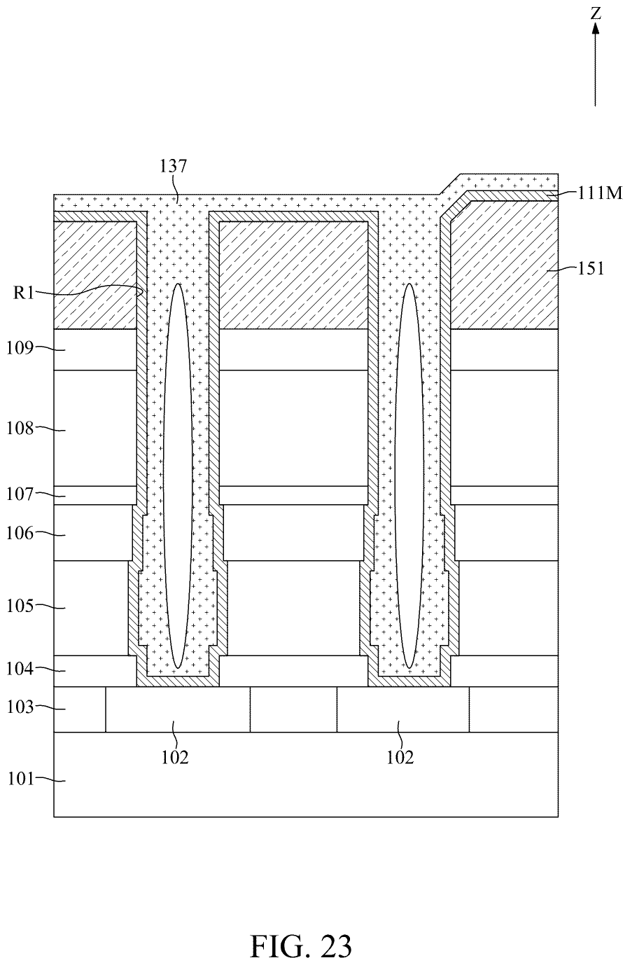

With reference to FIG. 23, the sacrificial material 137 may be formed with a procedure similar to that illustrated in FIG. 8, and descriptions thereof are not repeated herein.

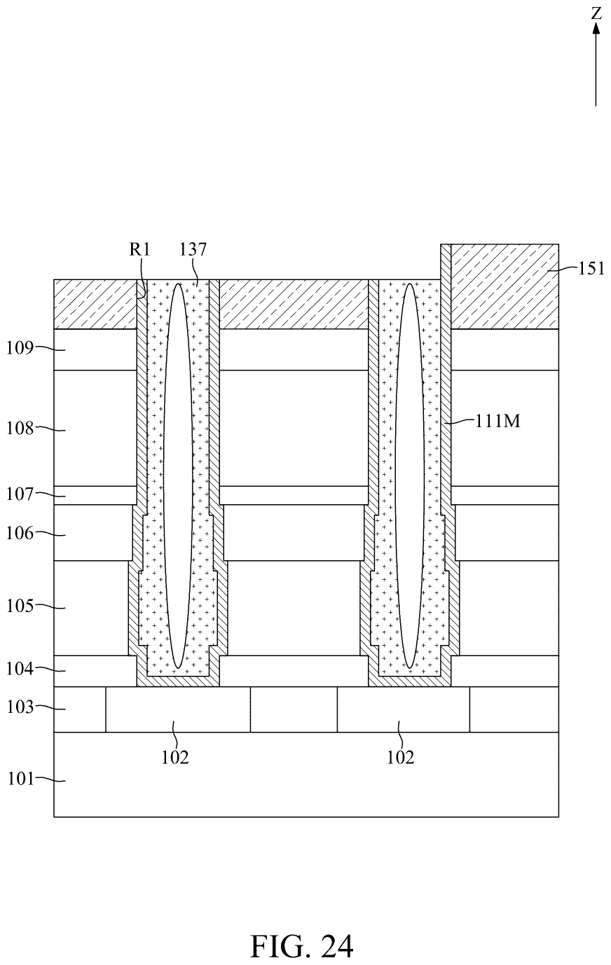

With reference to FIG. 24, a planarization process may be performed with a procedure similar to that illustrated in FIG. 9, and descriptions thereof are not repeated herein.

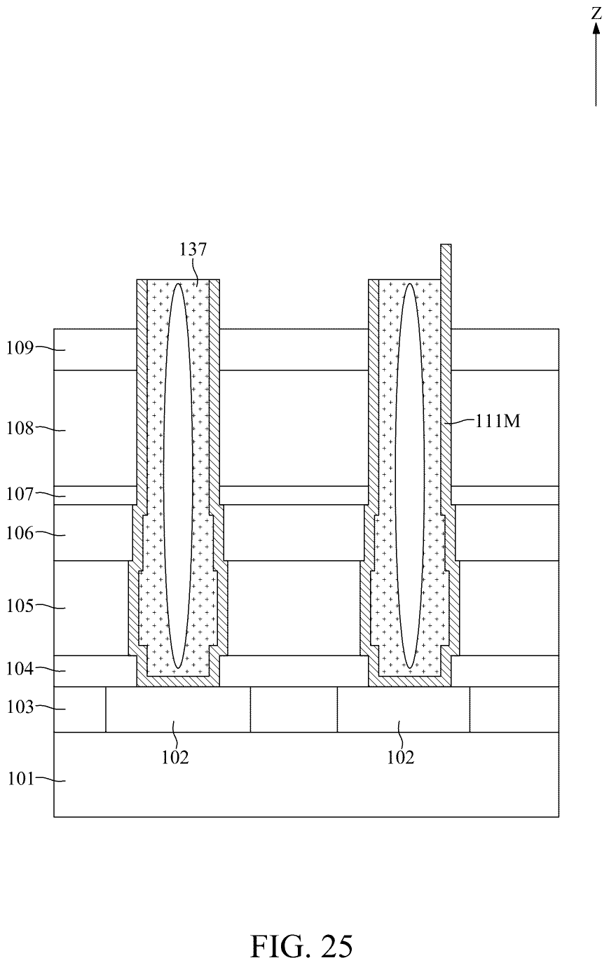

With reference to FIG. 25, the bottom mask layer 151 may be removed with a procedure similar to that illustrated in FIG. 10, and descriptions thereof are not repeated herein.

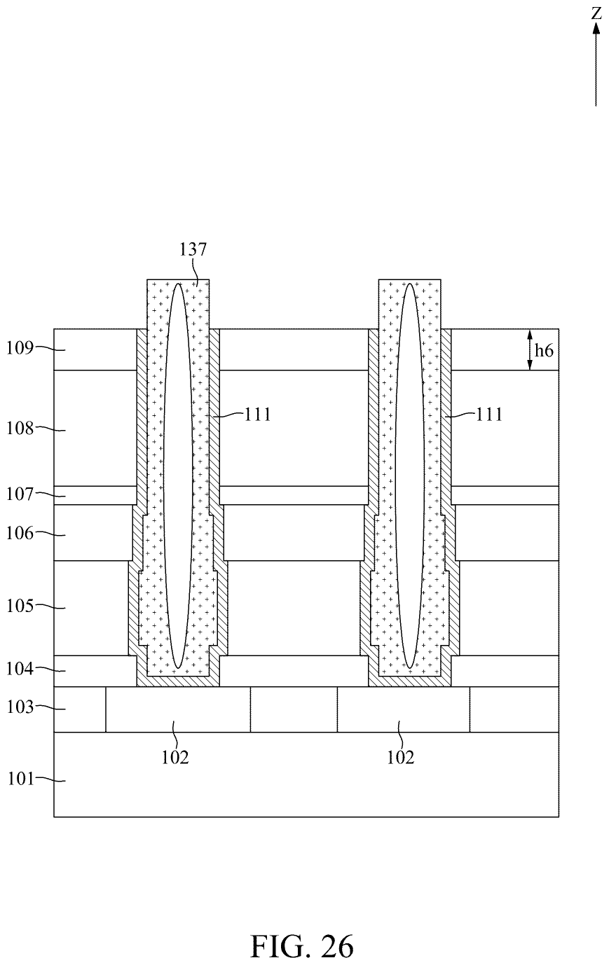

With reference to FIG. 26, the bottom electrodes 111 may be formed with a procedure similar to that illustrated in FIG. 11, and descriptions thereof are not repeated herein.

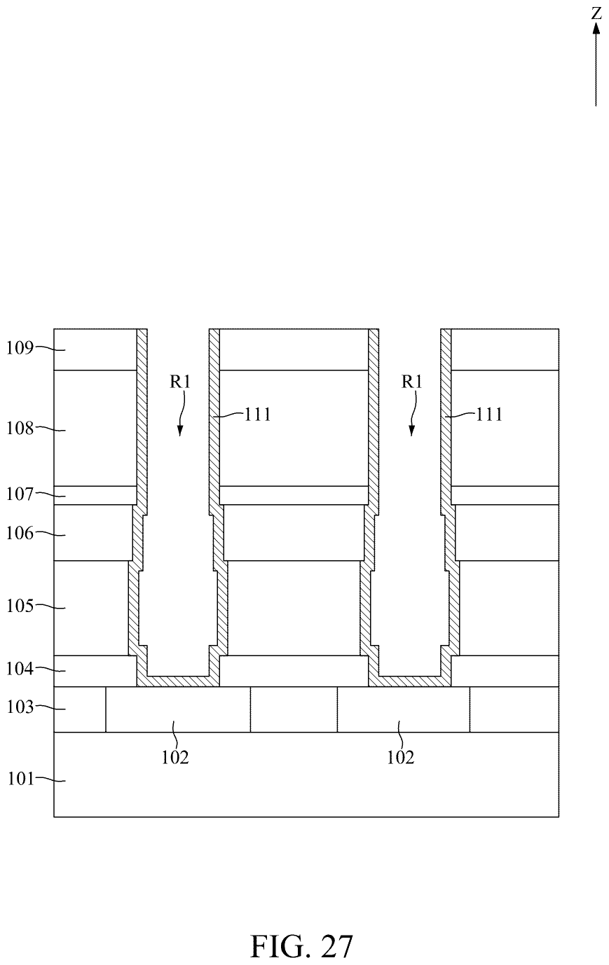

With reference to FIG. 27, the sacrificial material 137 may be removed with a procedure similar to that illustrated in FIG. 12, and descriptions thereof are not repeated herein.

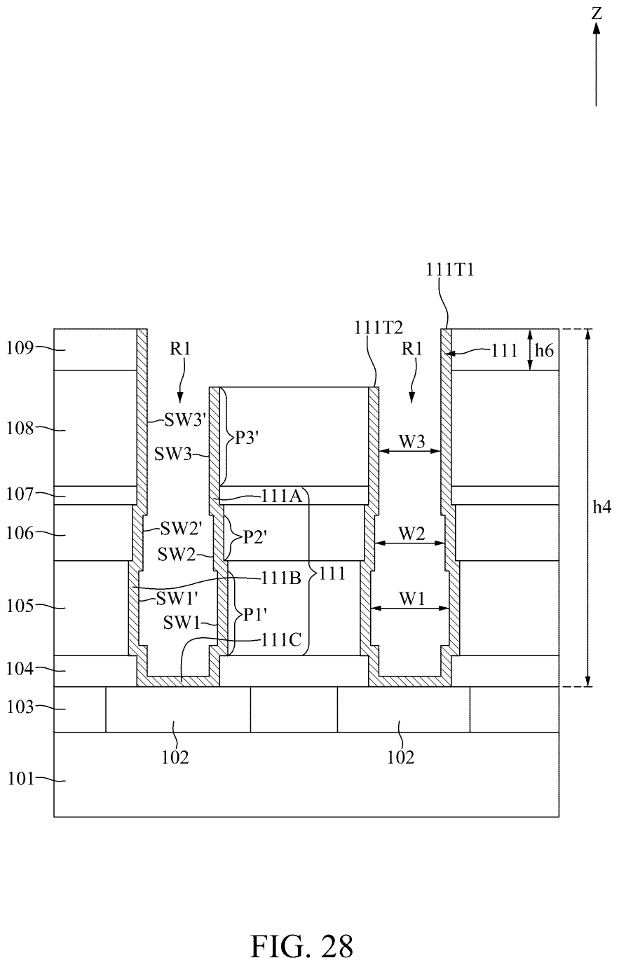

With reference to FIG. 28, the cutoff region J1 may be recessed with a procedure similar to that illustrated in FIGS. 13 and 14, and descriptions thereof are not repeated herein. After the cutoff region J1 is recessed, the first recess R1 may be defined by the bottom electrode 111. In some embodiments, the first recess R1 may include a lower portion P1′, a middle portion P2′, and an upper portion P3′. The lower portion P1′ may have a first width W1 measured from a first inner sidewall SW1 of the lower portion P1′ to a second inner sidewall SW1′ of the lower portion P1′, the middle portion P2′ may have a second width W2 measured from a third inner sidewall SW2 of the middle portion P2′ to a fourth inner sidewall SW2′ of the middle portion P2′, and the upper portion P3′ may have a third width W3 measured from a fifth inner sidewall SW3 of the upper portion P3′ to a sixth inner sidewall SW3′ of the upper portion P3′.

In some embodiments, the first width W1 may be greater than the second width W2. In some embodiments, the second width W2 may be greater than the third width W3. In some embodiments, the first width W1 may be greater than either the second width W2 or the third width W3.

In some alternative embodiments, the third width W3 may be comparable to the second width W2, and the second width W2 may be comparable to the first width W1.

In some embodiments, the thickness ratio of the thickness h6 of the third support layer 109 to the thickness h4 of the bottom electrode 111 may be between about 3.0% and about 8.0% or between about 3.3% and about 7.5%. In some embodiments, the thickness h4 of bottom electrode 111 may be in a range from 0.8 μm to about 1.2 μm.

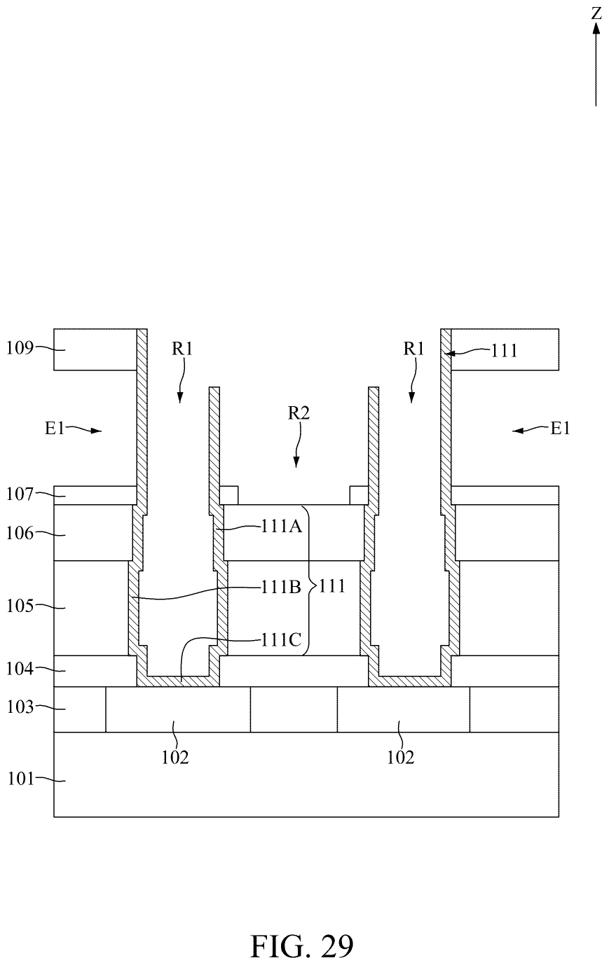

With reference to FIG. 29, the top material layer 108 may be removed and the second recess R2 may be formed with a procedure similar to that illustrated in FIG. 15, and descriptions thereof are not repeated herein.

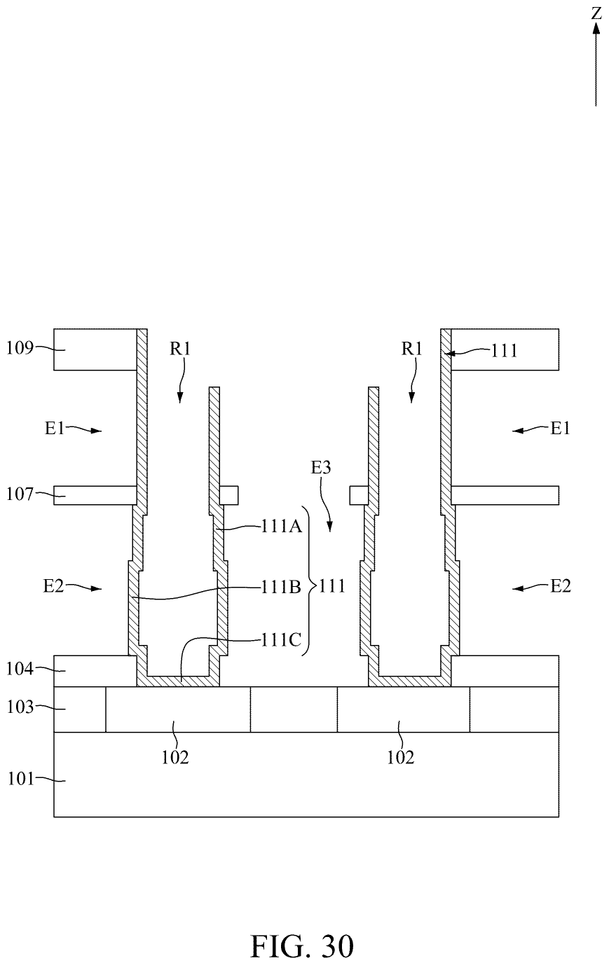

With reference to FIG. 30, the first material layer 105 and the second material layer 106 may be removed by a removal process. In some embodiments, the removal process may include applying NF₃ and H₂, along with an application of plasma, over the first material layer 105 and the second material layer 106. Such a removal process may have an etching rate on Si significantly greater than an etching rate on SiN, for example, around 2000:1. After performing the removal process, the second support layer 107 may remain adhered to the bottom electrode 111 and overhang the first support layer 104. In some embodiments, the etching chemical may enter through the second recess R2 depicted in FIG. 29. In some embodiments, the second support layer 107 may be attached to the second wall portion 111B and the first wall portion 111A of the bottom electrode 111. The top surface 104T of the first support layer 104 may be exposed. The empty space E2 may be formed between the first support layer 104 and the second support layer 107. The empty space E3 may be formed between the first wall portions 111A of the bottom electrodes 111.

In summary, the first material layer 105, the second material layer 106, and the top material layer 108 are removed. The first support layer 104, the second support layer 107, the third support layer 109, and the bottom electrodes 111 remain in place.

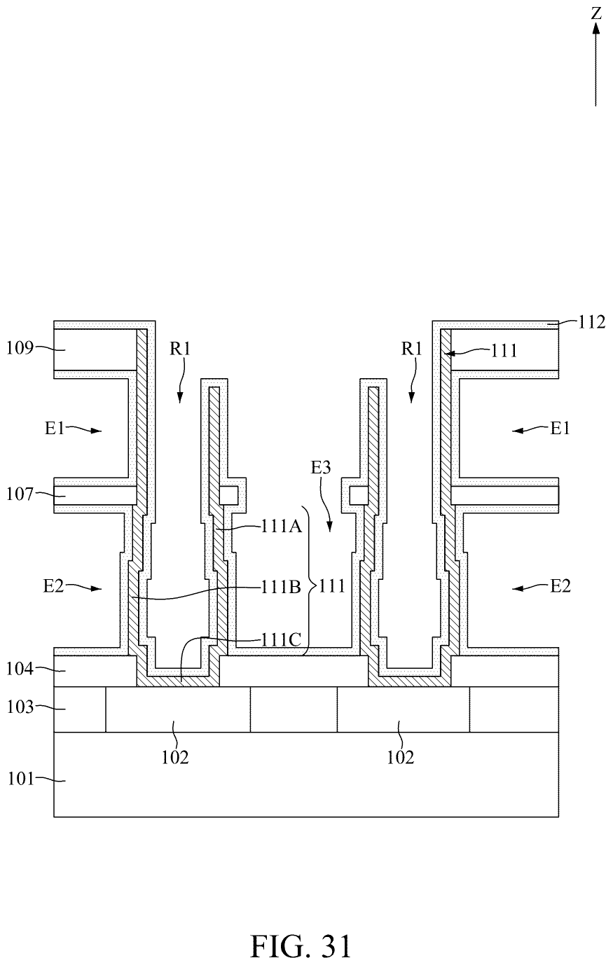

With reference to FIG. 31, the dielectric layer 112 may be formed with a procedure similar to that illustrated in FIG. 17, and descriptions thereof are not repeated herein.

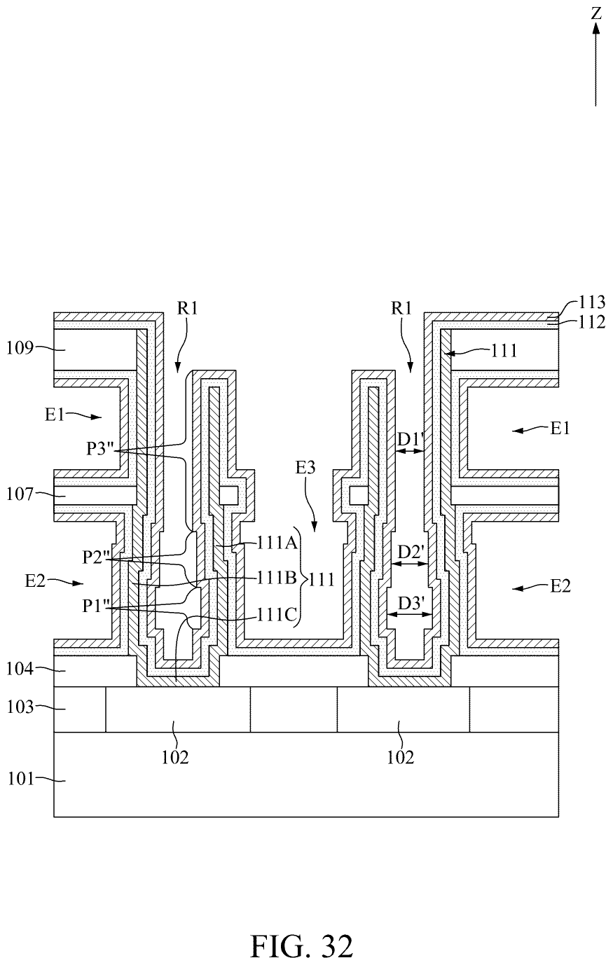

With reference to FIG. 32, the top electrode 113 may be formed with a procedure similar to that illustrated in FIG. 18, and descriptions thereof are not repeated herein. After the formation of the top electrode 113, the first recess R1 may be defined by the top electrode 113. In some embodiments, the first recess R1 may include a lower portion P1″, a middle portion P2″, and an upper portion P3″. In some embodiments, the first recess R1 may have a dimension D1′ at a level of the lower portion P1″, a dimension D2′ at a level of the middle portion P2″, and a dimension D3′ at a level of the upper portion P3″. In some embodiments, the dimension D1′ may be greater than the dimension D2′. In some embodiments, the dimension D2′ may be greater than the dimension D3′. In some embodiments, the dimension D1′ may be greater than either the dimension D2′ or the dimension D3′. The dimensions D1′, D2′ and D3′ are maximum widths in a lateral direction of a corresponding empty space of the first recess R1.

In some embodiments, the dimension D1′ may be comparable to the dimension D2′, and the dimension D2′ may be comparable to the dimension D3′.

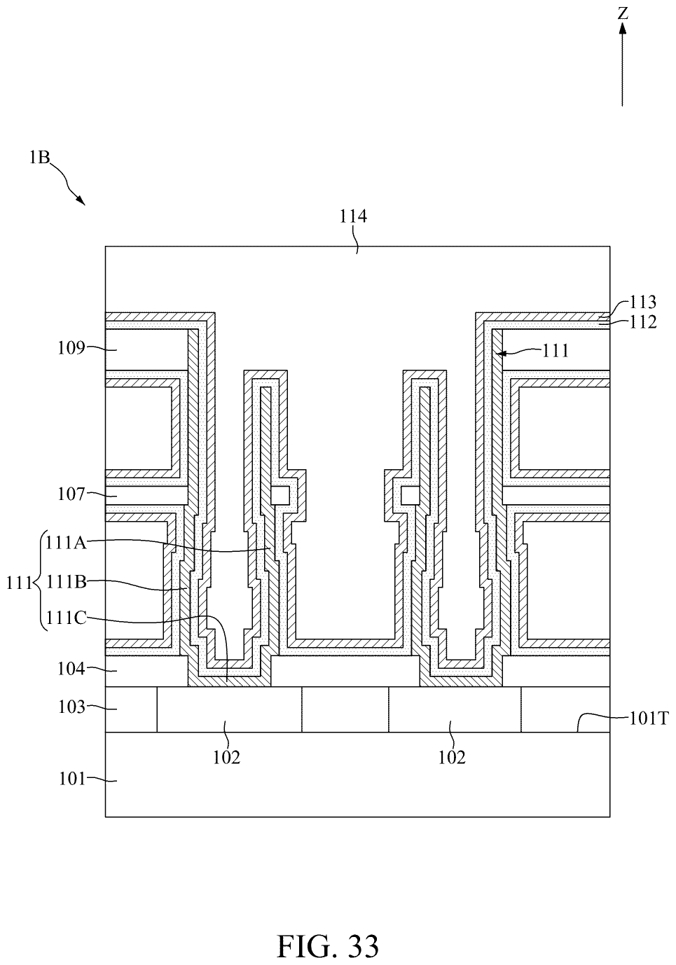

With reference to FIG. 33, the grounding layer 114 may be formed with a procedure similar to that illustrated in FIG. 19, and descriptions thereof are not repeated herein.

One aspect of the present disclosure provides a semiconductor device including a substrate; a bottom electrode positioned over the substrate and including a container-shaped profile; and a top support layer overhung the substrate and attached to the bottom electrode. A thickness ratio of a thickness of the top support layer to a thickness of the bottom electrode is between about 3.0% and about 8.0%.

Another aspect of the present disclosure provides a semiconductor device including a substrate; a bottom electrode including a bottom portion positioned over the substrate and extending parallel to a top surface of the substrate, a first wall portion extending upward and from the bottom portion, and a second wall portion extending upward and from the bottom portion, and distant from the first wall portion; a first support layer positioned over the substrate and surrounding the first wall portion and the second wall portion; a second support layer positioned over the first support layer and surrounding the first wall portion and the second wall portion; and a third support layer positioned over the second support layer and surrounding the second wall portion. A thickness ratio of a thickness of the top support layer to a thickness of the bottom electrode is between about 3.0% and about 8.0%.

Another aspect of the present disclosure provides a method for fabricating a semiconductor device including forming a landing area over a substrate; sequentially forming a first support layer, a first material layer, a second support layer, a top material layer, a third support layer, and a bottom mask layer over the landing area; forming a first recess penetrating the bottom mask layer, the third support layer, the top material layer, the second support layer, the first material layer, and the first support layer and exposing the landing area; conformally forming a bottom electrode material layer on the bottom mask layer and the first recess, forming a sacrificial material to fill the first recess, and performing a planarization process to expose the bottom mask layer; performing a first etching process to selectively remove the bottom mask layer; performing a second etching process to selectively remove the bottom electrode material layer above the third support layer to turn the bottom electrode material layer into a bottom electrode; and performing a third etching process to remove the sacrificial material. An etching rate ratio of the bottom mask layer to the third support layer is greater than 1000 during the first etching process. An etching rate ratio of the bottom electrode material layer to the third support layer is greater than 100 during the second etching process.

Due to the design of the semiconductor device of the present disclosure, the consumption of the third support layer 109 (or top support layer) may be significantly reduced due to the high etching selectivity of the first etching process and the second etching process. Hence, the remaining thickness of the third support layer 109 may be increased. As a result, the performance of the semiconductor device may be improved. In addition, by doping different dopants for different material layers 105, 106, and 108, the bottom of the first recesses R1 may be broadened. As a result, the performance of the semiconductor device may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a bottom electrode comprising:
a bottom portion positioned over the substrate and extending parallel to a top surface of the substrate;
a first wall portion extending upward and from the bottom portion; and
a second wall portion extending upward and from the bottom portion, and distant from the first wall portion;
a first support layer positioned over the substrate and surrounding the first wall portion and the second wall portion;
a second support layer positioned over the first support layer and surrounding the first wall portion and the second wall portion; and
a third support layer positioned over the second support layer and surrounding the second wall portion;
wherein a thickness ratio of a thickness of the top support layer to a thickness of the bottom electrode is between about 3.0% and about 8.0%.

2. The semiconductor device of claim 1, wherein the bottom electrode comprises:
a lower portion positioned between the first support layer and the second support layer;
a middle portion positioned over the lower portion and positioned between the first support layer and the second support layer; and
an upper portion positioned over the middle portion and positioned above the second support layer.

3. The semiconductor device of claim 2, wherein a width between a first inner sidewall of the lower portion to a second inner sidewall of the lower portion is greater than a width between a third inner sidewall of the middle portion to a fourth inner sidewall of the middle portion.

4. The semiconductor device of claim 2, wherein a width between a third inner sidewall of the middle portion to a fourth inner sidewall of the middle portion is greater than a width between a fifth inner sidewall of the upper portion to a sixth inner sidewall of the upper portion.

5. The semiconductor device of claim 2, wherein a width between a first inner sidewall of the lower portion to a second inner sidewall of the lower portion is greater than a width between a fifth inner sidewall of the upper portion to a sixth inner sidewall of the upper portion.

6. The semiconductor device of claim 2, wherein a width between a first inner sidewall of the lower portion to a second inner sidewall of the lower portion, a width between a third inner sidewall of the middle portion to a fourth inner sidewall of the middle portion, and a width between a fifth inner sidewall of the upper portion to a sixth inner sidewall of the upper portion are substantially the same.

7. The semiconductor device of claim 1, wherein a top surface of the first wall portion is lower than a top surface of the second wall portion.

8. The semiconductor device of claim 1, further comprising a dielectric layer conformally covering the bottom electrode, the first support layer, the second support layer, and the third support layer.

9. The semiconductor device of claim 8, further comprising a top electrode conformally covering the dielectric layer.

10. The semiconductor device of claim 9, further comprising a grounding layer positioned on the top electrode.
